(19) United States
(12) Patent Application Publication
(10) Pub. No.: US 2005/0285175 A1
(43) Pub. Date: Dec. 29, 2005

(54) Vertical SOI Device

(75) Inventors: Kangguo Cheng, Beacon, NY (US); Ramachandra Divakaruni, Ossining, NY (US); Oleg Glushenkov, Poughkeepsie, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/710,166

(22) Filed: Jun. 23, 2004

(51) Int. Cl. H01L 27/108; H01L 21/8242

(52) U.S. Cl. 257/302; 257/328; 438/268; 438/243

(57) ABSTRACT

The present invention provides a structure and method of forming vertical transistors. The structure of the present invention comprises: a substrate having an insulator layer formed thereon and a trench formed therein, the trench having an upper trench section extending through the insulator layer to an upper surface of the substrate and having a lower trench section extending from the upper substrate surface into the substrate; a semiconductor layer formed adjacent to the upper trench sidewalls; an upper terminal region and a lower terminal region formed in the semiconductor layer, where a channel region separates the upper terminal region from the lower terminal region; a gate insulator extending from the upper terminal region to the lower terminal region and in contact with the channel region; and a gate conductor formed on the gate insulator, the gate insulator isolating the gate conductor from the channel region.

### BACKGROUND OF INVENTION

1. Technical Field

The present invention relates to semiconductor devices and methods of manufacturing the same, and more particularly, to trench memory cells having improved device performance, simplified manufacturing processing, reduced back-to-back buried strap leakage, scalability to sub-100 nm generations, and method of manufacturing the same.

2. Background of the Invention

A dynamic random access memory (DRAM) cell typically includes an access field-effect transistor (FET) and a storage capacitor. The access FET allows the transfer of data charges to and from the storage capacitor during writing and reading operations. The data charges on the storage capacitor are periodically refreshed during a refresh operation.

Memory density is typically limited by a minimum lithographic feature size (F) that is imposed by lithographic processes used during fabrication. For example, the present generation of high density dynamic random access memories (DRAMs) which are capable of storing 256 megabits of data or more, typically require an area of 8F² per bit of data. There is a need in the art to provide even higher density memories in order to further increase data storage capacity and reduce manufacturing costs. Increasing the data storage capacity of semiconductor memories requires a reduction in the size of the access FET and storage capacitor of each memory cell. However, other factors, such as subthreshold leakage currents, parasitic leakage currents (e.g. junction leakage and back-to-back buried strap leakage), and alpha-particle induced soft errors, require that larger storage capacitors be used. Thus, there is a need in the art to increase memory density while allowing the use of storage capacitors that provide sufficient immunity to leakage currents and soft errors. There is also a need in the broader integrated circuit art for dense structures and fabrication techniques.

Some techniques utilize a vertical transistor in the memory cell in order to reduce the surface area of the chip required for the cell. Each of these proposed memory cells, although smaller in size than conventional cells, fail to provide at least one of the following: improved device performance by reducing junction leakage and junction capacitance, a simplified manufacturing process by eliminating deep ultra-violet (DUV) mask and trench fill processing for forming shallow trench isolation (STI), improved access FET drive current, reduced back-to-back buried strap leakage, and adequate operational characteristics at sub-100 nm dimensions.

For example, U.S. Pat. No. 6,573,561 (the '561 patent) issued to International Business Machines on Jun. 3, 2003, the disclosure of which is incorporated by reference herein, discloses a vertical transistor structure that is part of a DRAM cell. A pair of vertical n-channel transistors (100) are contained within a pair of DRAM cells (80) and separated by a portion of a silicon wafer (10) as shown in FIG. 1 of the '561 patent. Each vertical FET is formed along a sidewall of a trench which runs vertically into a substrate (10) as shown in FIG. 1 of the '561 patent. The vertical FET includes a source region (130), a drain region (108), a channel region (12) between the source and drain regions, a vertical polysilicon gate (140), and a gate dielectric (120) separating the vertical polysilicon gate from the channel region as shown in FIG. 1 of the '561 patent. The pair of vertical transistors is separated by the bulk silicon wafer, and therefore, they must be isolated from one another in order for the DRAM cells to operate properly.

Conventionally, to achieve sufficient device isolation, a shallow trench isolation (STI) structure is formed between adjacent transistors. Typically, STI structures are formed by a deep ultra-violet (DUV) mask processing step followed by a STI filling process, where the STI depth is about 0.5 um. STI processing often occupies a significant portion of the upper trench periphery, where the vertical access FETs reside. Up to two-thirds of the upper trench periphery may be occupied as a result of the STI process. A two-thirds reduction in the upper trench periphery would result in a two-thirds reduction in the width of the vertical access FET and thus reducing the drive strength of the access FET by up to two-thirds. Such a reduction in drive strength would severely slow down the device speed. Additionally, if the buried straps of adjacent devices are not isolated from one another, significant leakage can occur between the adjacent devices from adjacent buried strap outdiffusion (back-to-back leakage). Process steps for isolating adjacent access transistors and adjacent buried straps add to process complexity and cost. Without sufficient device isolation, scaling of memory arrays will be prohibited by parasitic leakage currents in that the capacitor storage elements cannot be reduced in size unless leakage currents are also reduced.

Additionally, conventional vertical array devices, such as the one illustrated in the '561 patent, also suffer from parasitic junction leakage, the same parasitic junction leakage that exists in conventional non silicon-on-insulator (SOI) horizontal transistors. This parasitic junction leakage occurs when the transistor source/drain regions interact with the bulk silicon wafer (or well structures). SOI technology greatly reduces parasitic leakage by utilizing a thin, isolated layer of silicon on a buried oxide layer, thus essentially eliminating parasitic capacitance by isolating the source/drain regions from the bulk silicon wafer (or well structures). The present state of the art lacks a suitable vertical array device having minimized parasitic leakage and adequate operational characteristics at sub-100 nm dimensions.

For example, U.S. Pat. No. 6,566,190 (the '190 patent) issued to Promos Technologies on May 20, 2003, the disclosure of which is incorporated by reference herein, discloses a vertical transistor structure that is part of a DRAM cell. A vertical transistor is formed along a sidewall of a trench which runs vertically into a substrate (10) as shown in FIG. 18 of the '190 patent. The vertical FET includes a source region and drain region (111), a channel region between the source and drain region and which is formed from the substrate, a vertical polysilicon gate (121), a gate dielectric (120) separating the vertical polysilicon gate from the channel region, and a STI region (160) as shown in FIG. 18 of the '190 patent. Additionally, a buried strap structure (100) connects the drain of the vertical transistor to one node (90) of the buried capacitor as shown in FIG. 11 of the '190 patent. Also, an internal thermal oxide layer (72) as shown in FIG. 13 of the '190 patent, which is formed by an angled implantation, is provided to isolate the vertical transistor device and the buried strap structure from the substrate. It is extremely difficult, if not impossible, to scale the vertical array structure as taught in the '193 patent to sub-100 nm dimensions because the angled implantation used to form the thermal oxide isolation layer is extremely challenging, if not inoperable, in narrow trenches at sub-100 nm dimensions. Furthermore, the method of forming the vertical array structure as taught by the '193 patent requires complex processing, including critical mask steps, and thus is more difficult to control, more prone to failure, and more costly.

As DRAM device design density requirements shrink below sub-100 nm dimensions, the formation of trenches and collars becomes extremely difficult. The conventional view is that at sub-100 nm ground rules, a vertical transistor is required to overcome parasitic leakage effects, and such a vertical transistor will enable a sub-8F² area trench DRAM layout.

Device development has also trended toward a fully depleted device design that improves speed and incorporates latch-up immunity. Such devices can be realized by a thin silicon-on-insulator (SOI) structure, since SOI devices are essentially free of latch-up. A large amount of successful research effort has been dedicated to the formation of robust SOI applications. However, heretofore, there has been little success in the formation of vertical SOI structures having improved device performance, simplified manufacturing processing, improved access FET drive current, reduced back-to-back buried strap leakage, and scalability to sub-100 nm dimensions, in-part due to process integration complexity.

### BRIEF DESCRIPTION OF DRAWINGS

The preferred exemplary embodiment of the present invention will hereinafter be described in conjunction with the appended drawings, where like designations denote like elements, and

FIG. 1 is a flow diagram illustrating a fabrication method of the invention;

FIGS. 2-20 are cross-sectional side views of an embodiment of a semiconductor structure of the invention during the fabrication method of FIG. 1.

FIGS. 21-24 are cross-sectional side views of an alternate embodiment of a semiconductor structure of the invention during the fabrication method of FIG. 1 integrated into an embedded DRAM process.

### BRIEF DESCRIPTION OF SEQUENCES

The present invention thus provides a device structure and method of forming vertical transistors for use in memory cells that overcome many of the disadvantages of the prior art. Specifically, the device structure and method provide improved device performance by reducing junction leakage and junction capacitance. Additionally, the device structure and method provide a simplified manufacturing process by eliminating DUV mask and trench fill processing for forming shallow trench isolation (STI). Furthermore, the device structure and method provide improved access FET drive current. Also, the device structure and method provide reduced back-to-back buried strap leakage. Finally, the device structure and method provide adequate operational characteristics at sub-100 nm dimensions.

In a first aspect, the invention is a vertical transistor comprising a substrate having an insulator layer formed thereon and a trench formed in the insulator layer and the substrate, the trench having an upper section with side-walls extending through the insulator layer to an upper surface of the substrate and having a lower section with sidewalls extending from the upper substrate surface into the substrate; an epitaxial semiconductor layer formed adjacent to the upper trench sidewalls; an upper terminal region and a lower terminal region formed in the epitaxial semiconductor layer, where the upper terminal region is separated from the lower terminal region by a channel region; a gate insulator extending from the upper terminal region to the lower terminal region and in contact with the channel region; and a gate conductor formed on the gate insulator, the gate insulator isolating the gate conductor from the channel region.

In a second aspect, the invention is the vertical transistor as previously described, further comprising a trench capacitor, where the trench capacitor is positioned in the lower trench section and is electrically coupled to the vertical transistor, the trench capacitor comprising: a first node arranged in the substrate; a second node positioned in the lower trench section, a node dielectric isolating the first node from the second node; and a buried strap for electrically coupling the second node to the lower terminal region.

In a third aspect, the invention is an integrated circuit comprising an array of memory cells each comprising a vertical transistor positioned above a trench capacitor and electrically coupled to the trench capacitor, the vertical transistor comprising a substrate having an insulator layer formed thereon and a trench formed in the insulator layer and the substrate, the trench having an upper section with sidewalls extending through the insulator layer to an upper surface of the substrate and having a lower section with sidewalls extending from the upper substrate surface into the substrate; an epitaxial semiconductor layer formed adjacent to the upper trench sidewalls; an upper terminal region and a lower terminal region formed in the epitaxial semiconductor layer, where the upper terminal region is separated from the lower terminal region by a channel region; a gate insulator extending from the upper terminal region to the lower terminal region and in contact with the channel region; and a gate conductor formed on the gate insulator, the gate insulator isolating the gate conductor from the channel region.

In a fourth aspect, the invention is the integrated circuit as previously described, with logic circuitry formed in a first portion of the substrate and the memory cells formed in a second portion of the substrate.

In a fifth aspect, the invention is a method of forming a vertical transistor, comprising the steps of: providing a substrate having an insulator layer formed thereon and a blocking cap layer formed on the insulator layer; forming an upper trench section in the insulator layer; forming a sacrificial spacer adjacent to the sidewalls of the upper trench section; forming a lower trench section in the substrate; removing the sacrificial spacer; forming an epitaxial semiconductor region adjacent the sidewalls of the upper trench section; forming a lower terminal region in a lower portion of the epitaxial semiconductor region; forming a gate insulator adjacent to the epitaxial semiconductor region; forming a gate conductor on the gate insulator; removing the blocking cap layer; and forming an upper terminal region in an upper portion of the epitaxial semiconductor region.

In a sixth aspect, the invention is the method as previously described, further comprising forming a trench capacitor in the lower trench section comprising the steps of: forming a buried plate in the substrate; forming a node dielectric adjacent to the buried plate; forming an inner node adjacent to the node dielectric, where the node dielectric isolates the inner node from the buried plate; and forming a buried strap adjacent to a lower surface of the epitaxial semiconductor region, where the buried strap couples the lower terminal region to the inner node.

In a seventh aspect, the invention is either method as previously described, prior to forming the upper trench section, further comprising: forming an insulator layer on the substrate; forming a blocking cap layer on the insulator layer; forming a nitride layer on the blocking cap layer over a first portion of the substrate; and forming logic circuitry in the first substrate portion.

The foregoing and other advantages and features of the invention will be apparent from the following more particular description of a preferred embodiment of the invention and as illustrated in the accompanying drawings.

### DETAILED DESCRIPTION

The present invention thus provides a device structure and method of forming vertical transistors for use in memory cells that overcome many of the disadvantages of the prior art. Specifically, the device structure and method provide improved device performance by reducing junction leakage and junction capacitance. Additionally, the device structure and method provide a simplified manufacturing process by eliminating deep ultra-violet (DUV) mask and trench fill processing for forming shallow trench isolation (STI). Furthermore, the device structure and method provide improved access FET drive current. Also, the device structure and method provide reduced back-to-back buried strap leakage. Finally, the device structure and method provide adequate operational characteristics at sub-100 nm dimensions.

The invention will next be illustrated with reference to the figures in which the same numbers indicate the same elements in all figures. Such figures are intended to be illustrative, rather than limiting, and are included to facilitate the explanation of the process and device of the present invention.

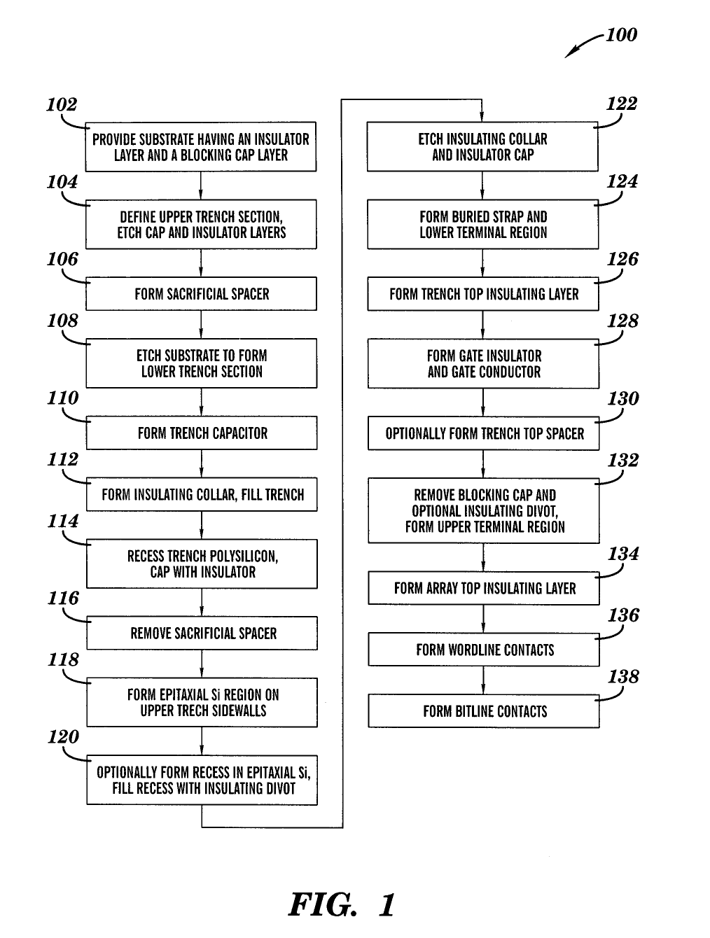

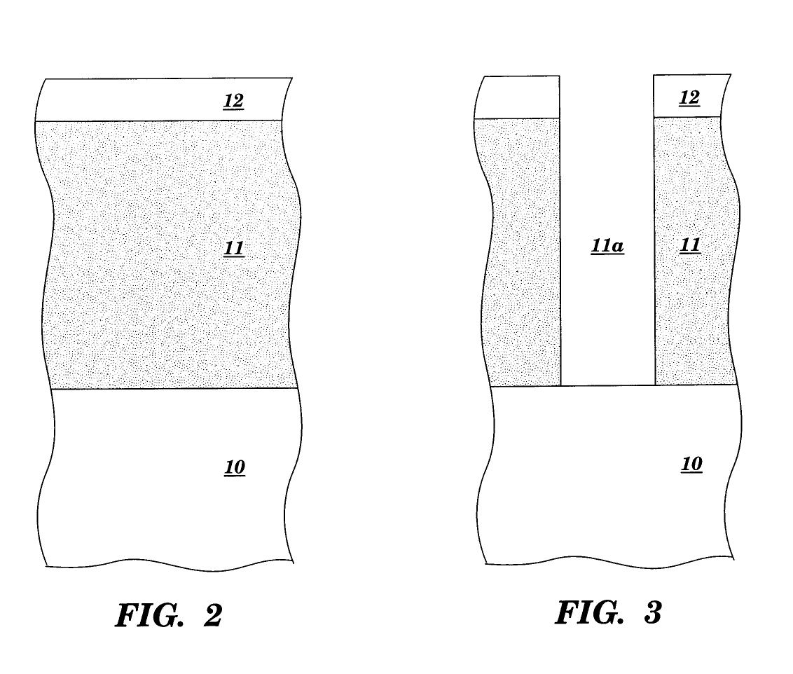

Turning now to FIG. 1, an exemplary method 100 for forming vertical transistors in accordance with the present invention is illustrated. The fabrication method 100 enables vertical transistors to be formed with improved device performance, simplified manufacturing processing, improved drive current, reduced back-to-back buried strap leakage, and scalability to sub-100 nm dimensions. Thus, method 100 provides the advantages of producing vertical transistors using a more reliable and cost-effective fabrication process. Method 100 will now be described in detail, along with examples of one embodiment of a wafer portion during process in FIGS. 2-20.

The first step 102 of FIG. 1 is to provide a suitable semi-conductor substrate having an insulator layer formed on the surface of the substrate and a blocking cap layer formed on the insulator layer. The substrate may comprise any semiconductor material, for example: Si, strained Si, Si_{1-y}C, Si_{1-x-y}GeₓC_{y}, Si₁₋ₓGeₓ, Si alloys, Ge, Ge alloys, GaAs, InAs, InP as well as other III-V and II-VI semiconductors. The insulator layer can be any suitable insulating material and is preferably oxide. The insulator layer can be formed by any conventional thermal growth or deposition process. For example, the insulator layer can be formed by low-pressure chemical vapor deposition (LPCVD), plasma-enhanced CVD (PECVD), or high-density plasma CVD (HDPCVD). The thickness of the insulator layer can range from approximately 50 nm to 1 um, preferably from 100 nm to 500 nm, and more preferably from 300 nm to 400 nm. The blocking cap layer protects the underlying insulator layer during subsequent processing and may be SiC, nitride, oxynitride, TERA (tunable etch-resistant ARC), or any suitable combination thereof. It also acts as a hardmask for forming a trench in the underlying insulator layer and the substrate. Preferably, the cap layer comprises SiC. The blocking cap layer can be formed by conventional processing such as deposition or thermal growth.

Turning now to FIG. 2, an exemplary semiconductor substrate 10 is illustrated having an oxide layer 11 formed on the surface of substrate 10 and a SiC cap layer 12 formed on oxide layer 11.

Returning to FIG. 1, the next step 104 of method 100 is to define the trench and to etch the blocking cap layer and underlying insulator layer to form an upper section of the trench in the insulator layer. The upper trench section is formed by patterning and etching the blocking cap layer and the underlying insulator, stopping on the substrate. Patterning can be done by any suitable process, and would typically involve the deposition and developing of a suitable photoresist. The photoresist can be developed using any suitable process such as optical lithography, electron beam lithography, x-ray lithography, or other conventional means for developing the photoresist. After the photoresist has been developed, the blocking cap layer and the underlying insulator layer can then be etched selective to the developed photoresist using any conventional etch process, for example, reactive ion etch (RIE).

Turning now to FIG. 3, semiconductor substrate 10 is illustrated after SiC cap layer 12 and oxide layer 11 have been patterned and etched to form upper trench section 11a.

Returning to FIG. 1, the next step 106 is to form a sacrificial spacer along the sidewalls of the upper trench section. This can be done using any suitable process, and would typically involve the deposition of a suitable material (e.g., by LPCVD) followed by a RIE process. Preferably, the sacrificial spacer can be a nitride layer such as silicon nitride having a thickness ranging approximately from 5 nm to 500 nm, preferably 20 nm to 200 nm, and more preferably from 50 nm to 100 nm. As will become clear, the formation of a sacrificial spacer along the sidewalls of the upper trench section will enable the creation of an epitaxial silicon layer adjacent the upper trench sidewalls in which the vertical transistor of the present invention will be formed.

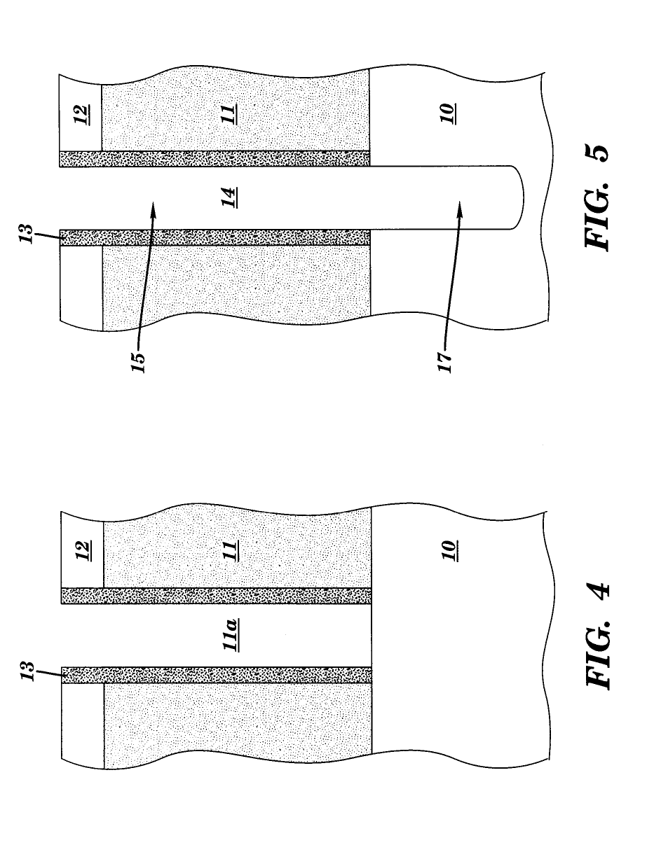

Turning now to FIG. 4, semiconductor substrate 10 is illustrated after sacrificial silicon nitride spacer 13 has been formed along the sidewalls of upper trench section 11a.

Returning to FIG. 1, the next step 108 is to complete the formation of the trench structure by forming a lower trench section in the substrate. The lower trench section is formed in the substrate by etching the portion of the substrate not protected by the blocking cap layer (the SiC cap layer acts as a hardmask during the etching of the lower trench section). Once the lower trench section is formed in the substrate, the trench structure is complete and comprises the upper trench section and the lower trench section. The lower trench section may be etched into the substrate using any conventional etch technique such as RIE. The sacrificial spacer protects the sidewalls of the upper trench section during the etch process. As a result, the upper trench section formed in the oxide layer will be wider than the lower trench section. As will become clear, the wider upper trench section will enable the formation of an epitaxial silicon layer adjacent the sidewalls of the upper trench section.

Turning now to FIG. 5, semiconductor substrate 10 is illustrated after trench 14 has been formed. Trench 14 comprises upper trench section 15 formed in oxide layer 11 and lower trench section 17 formed in substrate 10. As will become clear, a trench capacitor will subsequently be formed in the lower trench section.

Returning to FIG. 1, the next step 110 is to form a trench capacitor in the lower trench section. First, the outer capacitor node is formed. The outer capacitor can be formed from the substrate as-is or a buried plate can optionally be formed in the substrate. The buried plate is a portion of the substrate which is heavily doped. The buried plate may be formed by any conventional process, such as gas phase doping, liquid phase doping, plasma doping, plasma immersion ion implantation, outdiffusion doping from a solid film such as arsenic doped silicate glass, or any combination thereof, which are all well known in the art. Optionally, enhancement of the trench capacitance can be done before or after buried plate formation. Capacitance can be enhanced by forming a bottle-shape in the lower trench section, roughening the sidewalls of the lower trench section by forming hemispherical silicon grains (HSG) thereon, or by any other suitable conventional trench capacitance enhancement method. The combination of two or more of these conventional approaches, such as the combination of bottling and HSG, can be performed. Next, a capacitor node dielectric is formed. The node dielectric can be any suitable dielectric such as nitride, oxide, oxynitride, Al2O3, ZrO2, HfO2, or any suitable combination thereof. Conventional techniques such as deposition and/or thermal growth can be used to form the node dielectric. Finally, the inner capacitor node is formed by filling the trench with a suitable conducting material such as doped polysilicon, doped germanium, metals, silicides, metallic nitride (e.g., TiN or TaN). Preferably the conducting material is doped polysilicon formed by LPCVD. The polysilicon-filled lower trench section will form the inner node of the trench capacitor while the buried plate will form the outer node.

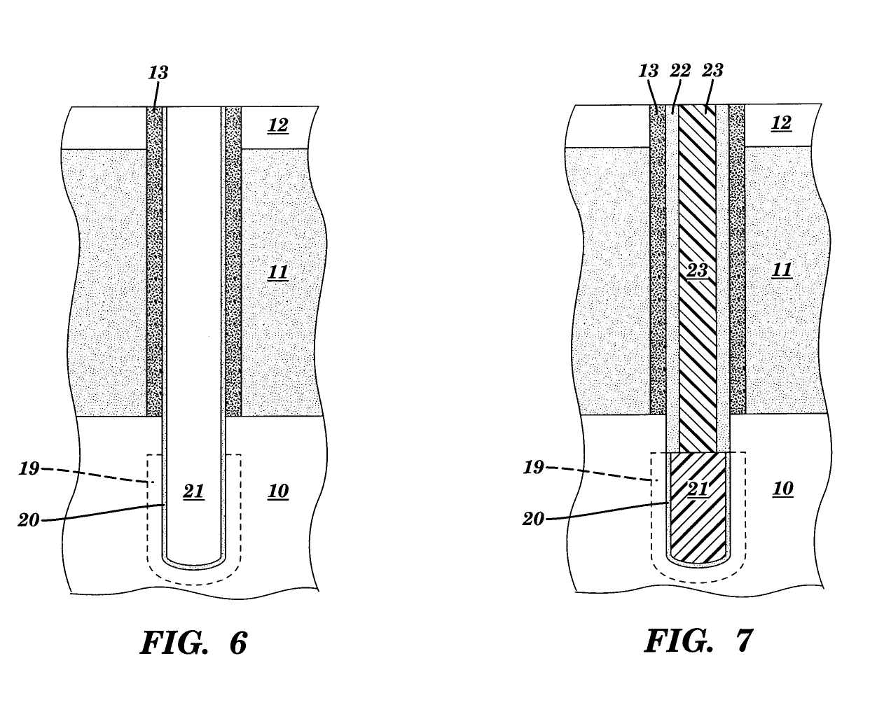

Turning now to FIG. 6, semiconductor substrate 10 is illustrated after the trench is filled with polysilicon 21. The trench capacitor can be formed from buried plate 19, node dielectric 20 and polysilicon 21.

Returning to FIG. 1, the next step 112 is to form an insulating collar for isolating the inner node of the trench capacitor from an upper side portion of the substrate and eventually from the vertical transistor and also to fill the trench. First, the conductor-filled trench is recessed below the surface of the substrate by a RIE process to form the inner node of the trench capacitor. Next, an insulating collar is formed on the upper sidewalls of the lower trench section and on the sidewalls of the upper trench section. Optionally, the capacitor node dielectric can be removed from the upper sidewalls of the lower trench section and from the surface of the sacrificial silicon nitride spacer before forming the collar. The collar can comprise any suitable insulating material such as oxide and may be formed by any conventional deposition process (e.g., LPCVD) followed by a RIE process. The thickness of the collar can range from 10 nm to 100 nm, preferably from 20 nm to 50 nm, and most preferably from 25 to 30 nm. Finally, the portion of the trench extending up from the inner capacitor node is filled with a conducting material such as doped polysilicon, doped germanium, metals, silicides, metallic nitrides (e.g., TiN or TaN). Preferably the conducting material is doped polysilicon formed by LPCVD. The conducting material is isolated from the sacrificial silicon nitride spacer and from the upper side surface of the substrate by the insulating collar. A planarization process such as CMP can be optionally performed.

Turning now to FIG. 7, semiconductor substrate 10 is illustrated after oxide collar 22 has been formed and the trench has been filled with polysilicon 23. Polysilicon 23 is isolated from sacrificial silicon nitride spacer 13 and from the upper side surface of substrate 10 by oxide collar 22. The trench capacitor will be formed from buried plate 19, node dielectric 20 and inner capacitor node 21.

Returning to FIG. 1, the next step 114 is to recess the polysilicon-filled trench and subsequently form an insulator cap on the recessed polysilicon for preventing Si growth on the remaining polysilicon during the subsequent epitaxial growth process. First, the polysilicon-filled trench is recessed by any conventional etch process such as RIE or wet etching. The recessed polysilicon will function as a terminal for the inner capacitor node and will electrically couple one node of the vertical transistor to the inner capacitor node. Next, an insulating cap layer is formed atop the recessed polysilicon. This cap layer will prevent silicon growth on the recessed polysilicon during subsequent epitaxial growth processes. Preferably, the cap layer can be formed by oxidation or nitridation of the recessed polysilicon. Alternatively, the cap layer can be formed by any conventional deposition process. If the cap layer is formed by deposition, it can be formed on the sidewall of the collar and atop the recessed poly.

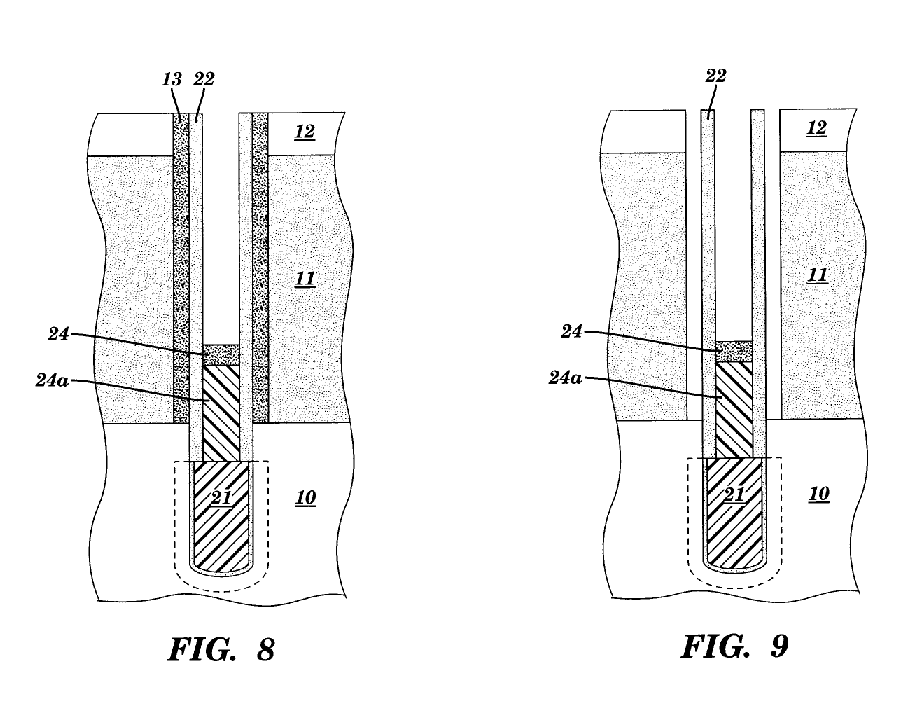

Turning now to FIG. 8, semiconductor substrate 10 is illustrated after the polysilicon-filled trench has been recessed and insulator cap layer 24 has been formed on inner capacitor node terminal 24a.

Returning to FIG. 1, the next step 116 is to remove the sacrificial spacer to form a gap between the collar and the insulator layer.

Turning now to FIG. 9, semiconductor substrate 10 is illustrated after sacrificial silicon nitride spacer 13 has been removed, thus forming a gap between oxide collar 22 and oxide layer 11. A hot phosphoric acid (H₃PO₄) process may be used to remove the sacrificial nitride spacer. As will become clear, the gap formed between oxide collar 22 and oxide layer 11 will subsequently be filled with a Si layer epitaxially grown from substrate 10.

Returning to FIG. 1, the next step 118 is to form an epitaxial Si region adjacent to the sidewalls of the upper trench section. The epitaxial Si region can be formed from the substrate and fills the gap formed between the insulating collar and the insulator layer, resulting in a vertical silicon-on-insulator (SOI) region. The epitaxial Si region can be formed by any suitable conventional selective growth process. For example, ultra-high vacuum chemical vapor deposition (UHVCVD) may be used to grow a device-quality epitaxial silicon layer. Other conventional techniques can be used such as rapid thermal chemical vapor deposition (RTCVD), low-pressure chemical vapor deposition (LPCVD), limited reaction processing CVD (LRPCVD) and molecular beam epitaxy (MBE). The epitaxial Si region can be doped with germanium and/or carbon to form Si₁₋ₓGeₓ and/or Si_{1-x-y}GeₓC_{y} by adding a germanium and/or carbon species during the epitaxial process. The value of x for the Si₁₋ₓGeₓ preferably ranges from 0.05 to 0.8, more preferably from 0.2 to 0.5, and most preferably about 0.35. Preferably, the value of y for the Si_{1-x-y}GeₓC_{y} is less than 0.02. More preferably, the value of y is about 0.005.

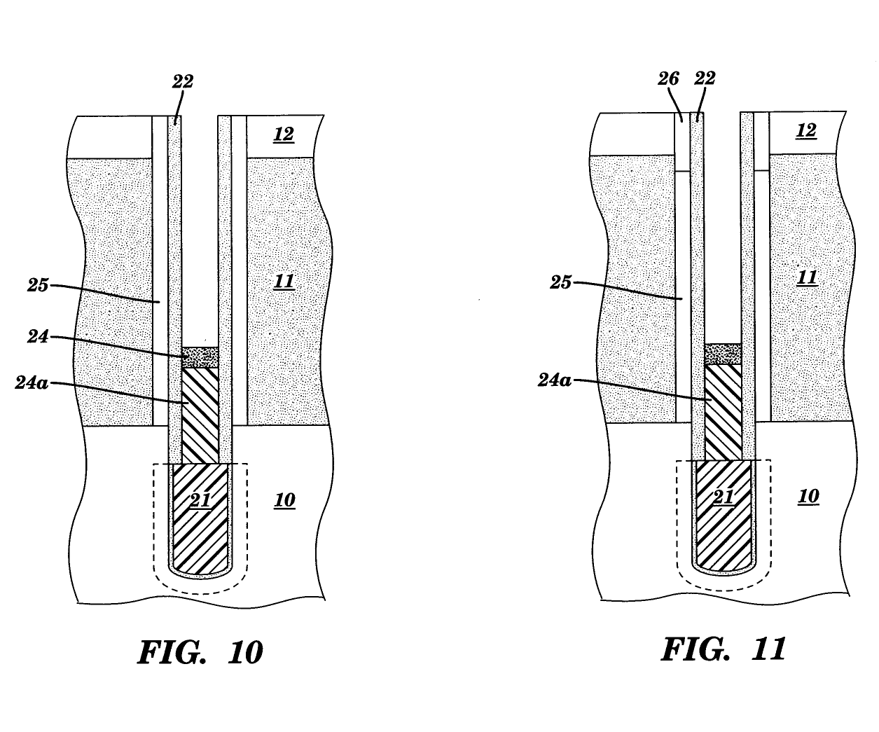

Turning now to FIG. 10, semiconductor substrate 10 is illustrated after epitaxial Si region 25 has been formed adjacent to the sidewalls of the upper trench section, the upper trench section being formed in oxide layer 11. Oxide cap layer 24 formed on inner capacitor node terminal 24a prevents silicon formation atop the terminal during the selective epitaxial SOI growth process. Additionally, epitaxial Si region 25 is surrounded by oxide layer 11, and therefore, is sufficiently isolated from other vertical epitaxial Si regions contained in adjacent trenches. Thus, there is no need for additional processing, such as STI processing, to form device isolation.

Returning to FIG. 1, the next step 120 is an optional step which is to form a recess in the epitaxial Si region and to fill the recess with an insulating material (divot). The epitaxial Si region can be recessed by any conventional etch process such as RIE or wet etch. Preferably, the epitaxial Si is recessed to, or slightly below, the interface between the insulator cap 12 and the surrounding oxide layer 11. The recess is then filled with an insulating material such as SiC, nitride, TERA, or any suitable combination thereof. The SiC divot will prevent the vertical SOI from being damaged during subsequent processes. Turning now to FIG. 11, semiconductor substrate 10 is illustrated after epitaxial Si region 25 has been recessed and filled with SiC divot 26.

Returning to FIG. 1, the next step 122 is to remove the insulating cap layer and to etch a portion of the insulating collar formed in the upper trench section. Any suitable etch process can be used to remove the insulating cap layer and to etch the insulating collar. For example, etch chemistry comprising HF may be used to etch the insulating collar formed in the upper trench section and to remove the insulating cap layer. The collar is recessed below the surface of the inner capacitor node terminal with a depth preferably ranging from 10 nm to 120 nm, more preferably from 30 nm to 80 nm, and most preferably from 50 nm to 60 nm, thus forming a divot between the vertical SOI and the inner capacitor node terminal. This divot can be filled with a conducting material in the subsequent process to form the buried strap. The buried strap will function as one terminal of the source/drain regions of the subsequently formed vertical transistor and will be electrically coupled to the inner node of the underlying trench capacitor via the inner capacitor node terminal.

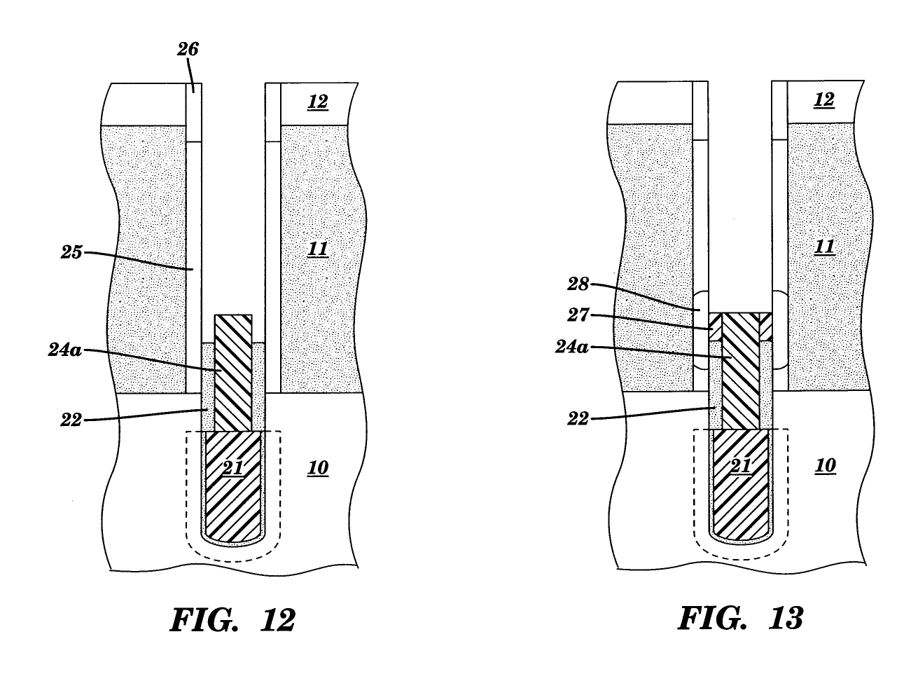

Turning now to FIG. 12, semiconductor substrate 10 is illustrated after an upper portion of oxide collar 22 has been etched and insulating cap layer 24 has been removed. A lower portion of oxide collar 22 remains after etching. This portion of the collar isolates inner capacitor node terminal 24a from substrate 10 and also isolates a lower portion of epitaxial Si region 25 from inner capacitor node terminal 24a. As will become clear, insulating cap layer 24 has been removed to facilitate the formation of the buried strap portion of the memory device.

Returning to FIG. 1, the next step 124 is to form a buried strap region and an outdiffusion region. The buried strap region functions as one terminal of the source/drain regions of the subsequently formed vertical transistor and is electrically coupled to the inner node of the underlying trench capacitor via the inner capacitor node terminal. The buried strap region is formed by filling the divot atop the recessed insulator collar and below the upper surface of the recessed polysilicon region. The divot may be a thin layer of undoped or doped polysilicon. During subsequent thermal processing, dopants, such as arsenic, out-diffuse into the lower epitaxial Si region, thereby forming the lower terminal region (source/drain) of the vertical transistor. In one embodiment, dopants can out-diffuse from the doped buried strap region. In another embodiment, where the buried strap region is not doped, the dopants can out-diffuse from the recessed polysilicon layer through the buried strap region. The divot can be formed by a deposition and etchback process. For example, a polysilicon layer with a thickness of 20 nm deposited by LPCVD process is sufficient to fill the divot which is about 30 nm wide and 60 nm deep. Polysilicon layer formed on the sidewall of the vertical SOI and atop of the inner node poly is removed by a timed wet chemical etch comprising ammonia-based chemistry. Alternatively, the polysilicon layer can be deposited by other deposition process such as plasma-enhanced CVD (PECVD), rapid thermal CVD (RTCVD), atomic-layer deposition (ALD), etc. The etchback of the polysilicon can be performed by any other suitable process such as a timed wet etch comprising nitric (HNO3) and hydrofluoric (HF). Optionally, a thin layer of thermal nitride of approximately 10 angstroms can be formed prior to the buried strap formation at the interface of the recessed polysilicon layer and the epitaxial Si region to prevent the formation of defects, such as dislocations.

Turning now to FIG. 13, semiconductor substrate 10 is illustrated after buried strap region 27 and lower terminal region 28 have been formed. Buried strap region 27 electrically couples lower terminal region 28 to inner capacitor node terminal 24a. Lower terminal region 28 forms the source (or drain) region of the vertical transistor, which will be subsequently formed in the upper trench section.

Returning to FIG. 1, the next step 126 is to form a trench top insulating layer on the buried strap region and the inner capacitor node terminal. Preferably, the insulting layer is a trench top oxide (TTO) layer. The trench top insulating layer can be formed by a deposition and etchback process. For example, due to the anisotropic nature of the high-density plasma HDPCVD process (the deposition rate of the HDP process is higher in the vertical direction than in the lateral direction), HDP oxide is formed with a thickness of approximately 25 nm on trench sidewall and 70 nm on top of both the buried strap and the inner capacitor node terminal. The HDP oxide on the trench sidewall is then removed by a timed wet etch comprising buffered HF (BHF) or diluted HF (DHF). The timed wet etch can remove approximately the same amount of HDP oxide on the buried strap region and the inner capacitor node terminal. Therefore, following the timed wet etch the resulting thickness of the TTO can be on the order of approximately 40 nm. Optionally, a sacrificial layer of thermal oxide, having a thickness of approximately 5 nm, can be formed before the TTO is deposited to protect the exposed surface of the epitaxial Si region from attack by the plasma during a HDPCVD process. If the optional sacrificial layer of thermal oxide is present, the sacrificial thermal oxide layer can be removed along with the HDP oxide by buffered HF (BHF) or diluted HF (DHF). The vertical channel of the epitaxial Si region can be doped at this stage by gas phase doping (GPD). Alternatively, ion implantation, plasma doping, plasma immersion ion implantation, liquid phase doping, solid phase doping, or any suitable combination thereof can be used.

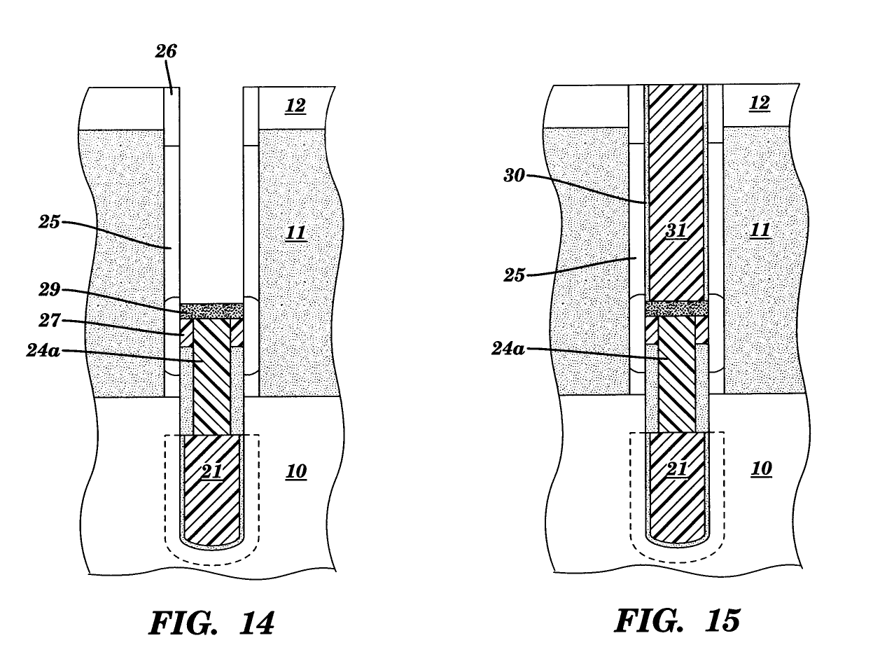

Turning now to FIG. 14, semiconductor substrate 10 is illustrated after trench top oxide (TTO) layer 29 has been formed. As will become clear, TTO layer 29 will provide isolation between the gate conductor and both the source/drain region of the vertical transistor and inner capacitor node terminal 24a.

Returning to FIG. 1, the next step 128 is to form a gate insulator and a gate conductor. The gate insulator can be formed by thermal oxidation. Alternatively, the gate insulator can be formed by a deposition process. The gate insulator can be any suitable insulator material. For example, the gate insulator can be oxide, nitride, oxynitride, Al2O3, ZrO2, HfO2, Ta2O3, TiO2, perovskite-type oxides or any suitable combination thereof, including multi-layer combinations thereof. The thickness of the gate insulator can range approximately from 2 nm to about 10 nm, preferably from 5 nm to 6 nm. After the gate insulator has been formed, the trench can then be filled with a gate conductor by conventional deposition processes, such as chemical vapor deposition (CVD), plasma-assisted CVD, high-density plasma chemical vapor deposition (HDPCVD), atomic-layer deposition (ALD), plating, sputtering, evaporation or chemical solution deposition. The gate conductor preferably is doped polysilicon, but may also comprise Ge, SiGe, SiGeC, metal silicides, metallic nitrides, metals (for example W, Re, Ru, Ti, Ta, Hf, Mo, Nb, Ni, Al) or any other suitable conductive material. Following deposition of the gate conductor, the gate conductor can be planarized by conventional planarization methods, such as chemical mechanical planarization (CMP).

Turning now to FIG. 15, semiconductor substrate 10 is illustrated after gate insulator 30 and gate conductor 31 have been formed. Gate insulator 30 is interposed between gate conductor 31 and epitaxial Si region 25 and isolates gate conductor 31 from epitaxial Si region 25.

Returning to FIG. 1, the next step 130 is an optional step which is to form a trench top insulating spacer between an upper portion of the gate conductor and both an upper portion of the epitaxial Si region and the blocking cap layer. Although the gate insulator alone can provide sufficient isolation, the optional trench top insulating spacer can further enhance the reliability of the vertical transistor by improving isolation between the gate conductor and the epitaxial Si region. First, the gate conductor is recessed below the upper surface of the surrounding insulator layer. The upper terminal region (source/drain) of the vertical transistor can be formed at this stage by doping the upper region of the SOI from the inner trench by any suitable doping process such as ion implantation, gas phase doping, liquid phase doping, solid phase doping, plasma doping, plasma immersion ion implantation, or any suitable combination thereof. Alternatively, the upper terminal can be formed during subsequent processing. Next, an insulating material such as nitride is deposited, for example, by LPCVD. Optionally, a thin thermal oxide can be grown prior to depositing the insulating material to enhance nitride adhesion. Next, an inner portion of the insulating material is etched (e.g. RIE) until the top surface of the recessed gate conductor is reached. The remaining portion of the insulating material forms a trench top insulating spacer. The etched portion of the insulating material is then filled with a conductor, preferably polysilicon. The gate conductor can be planarized, for example by CMP.

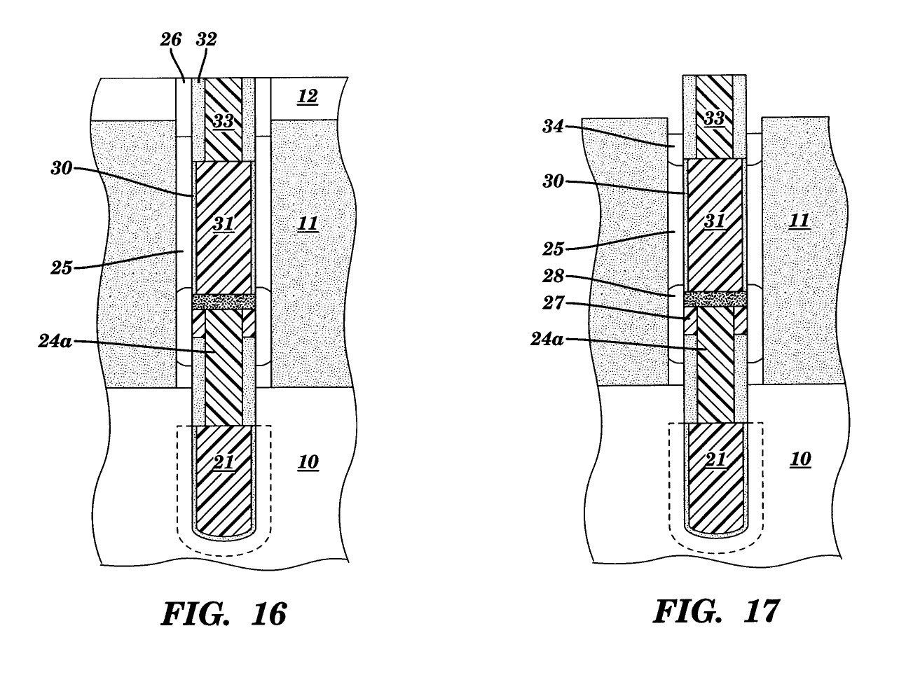

Turning now to FIG. 16, semiconductor substrate 10 is illustrated after trench top insulating spacer 32 has been formed. The gate conductor of the vertical transistor comprises lower gate conductor region 31 and upper gate conductor region 33. As a result of forming trench top insulating spacer 32, upper gate conductor region 33 is narrower than lower gate conductor region 31. Trench top insulating spacer 32 isolates upper gate conductor region 33 from an upper portion of epitaxial Si region 25. The insulating divot 26 protects the vertical SOI during the process of forming the spacer.

Returning to FIG. 1, the next step 132 is to remove the blocking cap layer and the optional insulating divot. The blocking cap layer and the insulating divot can be removed by any suitable conventional etch process such as dry etch (e.g., plasma etch or RIE), wet etch, or any suitable combination thereof. The upper terminal region (source/drain) of the vertical transistor can be formed at this stage by doping the upper region of the vertical SOI by any suitable doping process such as ion implantation, gas phase doping, liquid phase doping, solid phase doping, plasma doping, plasma immersion ion implantation, or any suitable combination thereof. Alternatively, the upper terminal can be formed as previously explained during the previous trench top insulating spacer process.

Turning now to FIG. 17, semiconductor substrate 10 is illustrated after SiC cap layer 12 and SiC divot 26 have been removed and after upper terminal region 34 has been formed. As will become clear, upper terminal region 34 and upper gate conductor region 33 will have contacts formed thereto, thus completing the vertical transistor of the present invention.

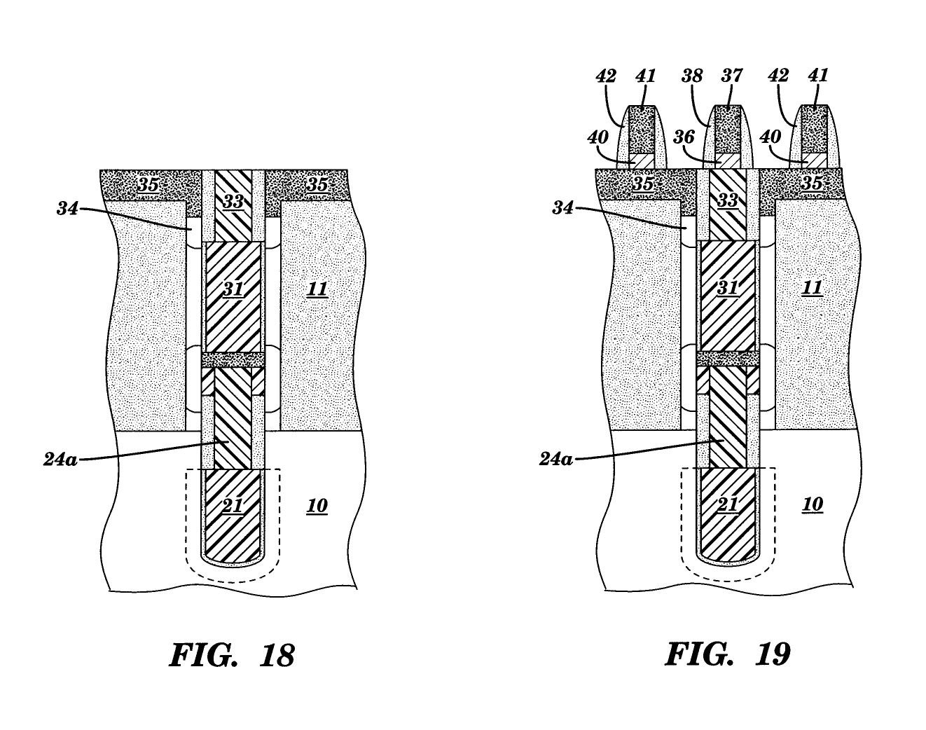

Returning to FIG. 1, the next step 134 is to planarize the surface of the structure by forming an array top insulating layer. The array top insulating layer is preferably an oxide layer formed by a deposition process such as HDPCVD, or any other suitable process. The array top insulating layer can then be planarized by a process such as CMP or any other suitable planarization process. Turning now to FIG. 18, semiconductor substrate 10 is illustrated after array top insulating layer 35 has been formed.

Returning to FIG. 1, the next step 136 is to form active and passing word line contacts. Each contact can include a conducting layer or layers, an insulating cap layer formed on top of the conducting layer(s), and an insulating spacer formed on the sidewalls of the wordline structure. Preferably, the conducting layer is a layer of tungsten with an optional layer of polysilicon underneath the tungsten. Alternatively, the conducting layer can comprise Ge, SiGe, SiGeC, metal silicides, metallic nitrides, metals (for example W, Re, Ru, Ti, Ta, Hf, Mo, Nb, Ni, Al) or any other suitable conductive material. The insulating cap layer preferably is a nitride layer, but can also comprise oxide, oxynitride, SiC or any other suitable insulating material. The conducting layer and the insulating layer can be formed by any suitable process such as chemical vapor deposition (CVD), low-pressure CVD (LPCVD), rapid thermal CVD (RTCVD), plasma enhanced CVD (PECVD), atomic-layer deposition (ALD), plating, sputtering, evaporation or chemical solution deposition. The insulating spacer preferably comprises a nitride layer with an optional oxide layer underneath the nitride layer. The passing wordline contacts are coupled to the next rows of trenches which are not illustrated in FIG. 19.

Turning now to FIG. 19, semiconductor substrate 10 is illustrated after the active and passing word line contacts have been formed. Active word line contacts are formed on top of upper gate conductor region 33 and comprise conducting layer 36, insulating cap 37, and spacer 38. Passing word line contacts are formed on top of array top insulating layer 35 and comprise conducting layer 40, insulating cap 41, and spacer 42. Wordlines may or may not be offset from the trench. FIG. 19 illustrates the non-offset case.

Returning to FIG. 1, the next step 138 is to form bitline contacts. First, an insulating layer such as boro-phos-pho-silicate glass (BPSG) is deposited and then patterned over the word line contacts to form contact stacks. Next, the array top insulating layer is etched to form contact areas to the upper terminal region of the vertical transistor. After etching the array top insulating layer, the open contact areas are filled with conducting material such as polysilicon or metal or any other suitable conducting material. Finally, the conducting material can be planarized by a process such as CMP or any other suitable planarization process.

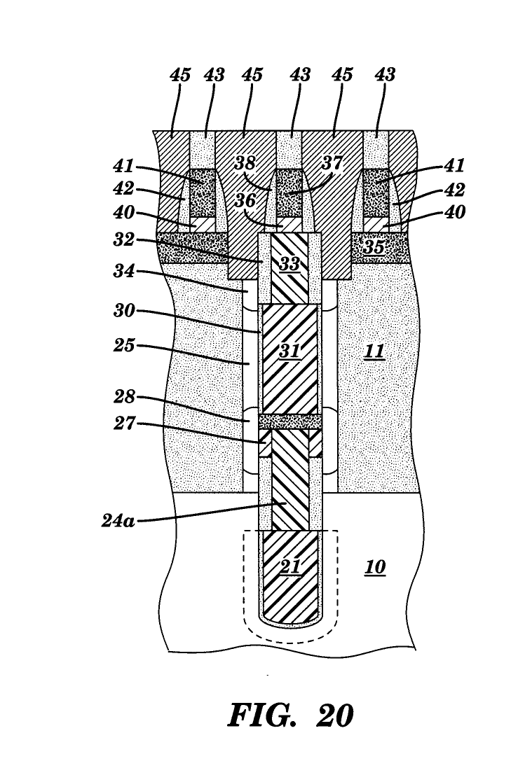

Turning now to FIG. 20, semiconductor substrate 10 is illustrated after bitline insulating layer 43 is etched and bitline contacts 45 have been formed. Array top insulating layer 35 has been etched to provide a contact region to upper terminal region 34. Bitline contacts 45 are coupled to upper terminal regions 34, thus completing all contacts to the vertical memory array of the present invention. Trench top insulating spacer 32 isolates upper gate conductor region 33 from both upper terminal region 34 and bitline contacts 45. Contact spacers 38 also isolate word-line contacts 36 and 40 from bitline contacts 45, thus electrically isolating wordlines from bitlines. The vertical transistor of the present invention has been formed. The vertical transistor comprises upper terminal region 34, lower terminal region 28, gate insulator layer 30, a gate conductor comprising lower gate conductor region 31 and upper gate conductor region 33, and a channel region formed by the section of epitaxial Si region 25 vertically interposed between upper terminal region 34 and lower terminal region 28. Upper terminal region 34 can be a drain region and lower terminal region 28 can be a source region. Lower terminal region 28 can be electrically coupled to inner capacitor node terminal 24a of the buried trench capacitor through buried strap 27. Active wordlines 36 contact upper gate conductor region 33 and bitlines 45 contact upper terminal regions 34. Because STI is not required to isolate adjacent vertical devices, none of the upper trench periphery is occupied as a result of STI processing. Therefore, the entire channel width of the vertical transistor is utilized, and thus, the drive strength of the access FET is not reduced.

During operation, the vertical transistor of the present invention can charge or discharge the buried trench capacitor when the wordline is active. The wordline activates the gate conductor, thus inverting the channel region of the vertical transistor. With the channel region inverted, inner node 21 of the buried trench capacitor can be either charged or discharged in response to the state of bitline 45. Charge is transferred from bitline 45 to inner capacitor node 21 through the following current path: bitline 45 to upper terminal region 34, upper terminal region 34 to lower terminal region 28 through the inverted channel of the vertical transistor, lower terminal region 28 to buried strap 27, buried strap 27 to inner capacitor node terminal 24a, and inner capacitor node terminal 24a to inner capacitor node 21.

The present invention thus provides a device structure and method for forming vertical transistors for use in memory cells that overcome many of the disadvantages of the prior art. Specifically, the device structure and method provide improved device performance by reducing junction leakage and junction capacitance. Additionally, the device structure and method provide a simplified manufacturing process by eliminating DUV mask and trench fill processing for forming shallow trench isolation (STI). Furthermore, the device structure and method provide improved access FET drive current. Also, the device structure and method provide reduced back-to-back buried strap leakage. Finally, the device structure and method provide adequate operational characteristics at sub-100 nm dimensions.

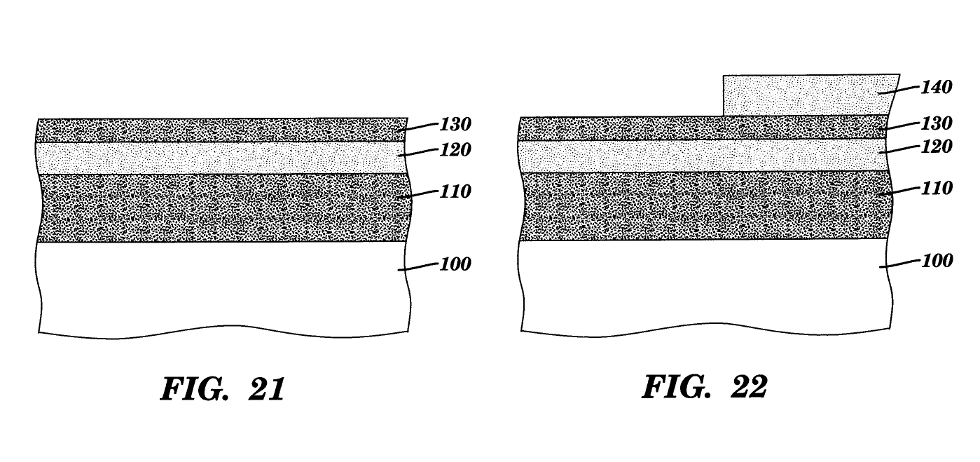

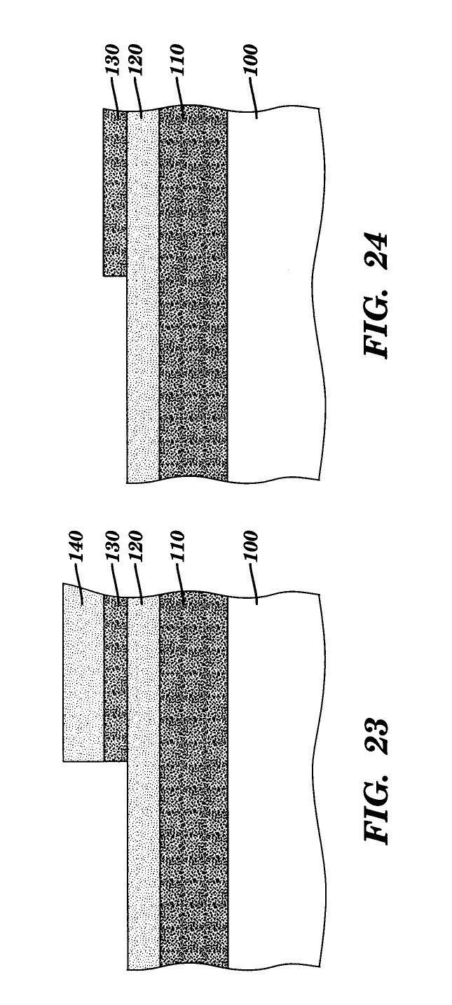

Optionally, the structure and method of the present invention can be implemented with embedded DRAM technologies, thus enabling the integration of logic circuitry and memory circuitry on the same substrate. At step 102 of FIG. 1, semiconductor substrate 100 is supplied having insulator layer 110 formed on the surface of the substrate, blocking cap layer 120 formed on the insulator layer, and pad material (e.g., nitride) 130 formed on the blocking cap layer as illustrated in FIG. 21. Before proceeding with step 104 of FIG. 1, the pad layer can be patterned using any suitable process, and would typically involve the deposition and developing of photoresist 140 as illustrated in FIG. 22. The photoresist can be developed using any suitable process such as optical lithography, electron beam lithography, x-ray lithography, or other conventional means for developing the photoresist. After the photoresist has been developed, pad nitride layer 130 can then be etched selective to developed photoresist 140 using any conventional etch process, for example, reactive ion etch (RIE) as illustrated in FIG. 23. The developed photoresist can then be removed by any suitable technique, for example a liquid resist strip process or an oxygen plasma process where the photoresist is oxidized (commonly referred to as ashing). Thus, as illustrated in FIG. 24, etched pad layer 130 remains only on that portion of the substrate which is to be protected during the subsequent vertical transistor processing steps 104 through 138 of FIG. 1 in accordance with the present invention. The portion of the substrate not protected by the nitride pad can then processed according to steps 104 through 138 of FIG. 1 to form vertical memory devices. Therefore, the protected portion of the substrate is preserved during the formation of vertical devices, thus enabling the formation of embedded DRAM circuitry and logic circuitry on the same substrate. Logic circuitry can be formed by any suitable conventional process and can comprise any suitable circuit type such as CMOS, bipolar, BiCMOS, system-on-chip (SoC), or any suitable combination thereof.

The embodiments and examples set forth herein were presented in order to best explain the present invention and its practical application and to thereby enable those of ordinary skill in the art to make and use the invention. However, those of ordinary skill in the art will recognize that the foregoing description and examples have been presented for the purposes of illustration and example only. The description as set forth is not intended to be exhaustive or to limit the invention to the precise form disclosed. Many modifications and variations are possible in light of the teachings above without departing from the spirit and scope of the forthcoming claims. Accordingly, unless otherwise specified, any components of the present invention indicated in the drawings or herein are given as an example of possible components and not as a limitation. Similarly, unless otherwise specified, any steps or sequence of steps of the method of the present invention indicated herein are given as examples of possible steps or sequence of steps and not as limitations.

1. A vertical transistor, comprising:
a substrate having an insulator layer formed thereon and a trench formed in said substrate and said insulator layer, said trench having an upper section with sidewalls extending through said insulator layer to an upper surface of said substrate and having a lower section with sidewalls extending from said upper substrate surface into said substrate;
a semiconductor region formed adjacent to at least one of said upper trench sidewalls;
an upper terminal region and a lower terminal region formed in said semiconductor region, wherein said upper terminal region is separated from said lower terminal region by a channel region;
a gate insulator extending from said upper terminal region to said lower terminal region and in contact with said channel region; and
a gate conductor formed on said gate insulator, said gate insulator isolating said gate conductor from said channel region.

2. The vertical transistor of claim 1, further comprising a trench top insulating spacer interposed between an upper side surface of said gate conductor and said upper terminal region, wherein said trench top insulating spacer isolates said gate conductor from said upper terminal region.

3. The vertical transistor of claim 1, further comprising a trench top insulating layer positioned below said gate conductor and in contact with a bottom surface of said gate conductor, wherein said trench top insulating layer isolates said gate conductor from said lower terminal region.

4. The vertical transistor of claim 3, further comprising a trench capacitor, wherein said trench capacitor is positioned in said lower trench section and is electrically coupled to said lower terminal region, said trench capacitor comprising:
a first node arranged in said substrate;
a second node positioned below said trench top insulating layer and isolated from said first node by a node dielectric, said second node filling said lower trench section and extending upward to a bottom surface of said trench top insulating layer, wherein said second node is isolated from said substrate by an insulating collar and isolated from said gate conductor by said trench top insulating layer; and
a buried strap interposed between an upper side surface of said second node and said lower terminal region and interposed between a top surface of said insulating collar and a bottom surface of said trench top insulating layer,
wherein said buried strap electrically couples said second node to said lower terminal region, is isolated from said gate conductor by said trench top insulating layer, and is isolated from said substrate by said insulating collar.

5. The vertical transistor of claim 1, wherein a distance between said upper terminal region and said lower terminal region is less than 100 nm.

6. The vertical transistor of claim 1, further comprising:
an electrical conductor positioned above said upper terminal region and in contact with said upper terminal region; and
a contact stack positioned above said gate conductor and in contact with said gate conductor.

7. The vertical transistor of claim 6, wherein said contact stack comprises:
a tungsten stud in contact with said gate conductor;
a silicon-nitride layer positioned on said tungsten stud;
a BPSG layer positioned on said silicon-nitride layer; and
an insulating contact spacer extending from a top side surface of said silicon-nitride layer to a bottom side surface of said tungsten stud, wherein said insulating contact spacer isolates said tungsten stud from said electrical conductor.

8. The vertical transistor of claim 1, wherein a thickness of said insulating layer ranges approximately from 50 nm to 1 um.

9. The vertical transistor of claim 1, wherein said substrate is selected from the group consisting of: Si, strained Si, Si_{1-y}C_{y}, Si_{1-x-y}GeₓC_{y}, Si₁₋ₓGeₓ, Si alloys, Ge, Ge alloys, GaAs, InAs, and InP.

10. The vertical transistor of claim 1, wherein said semiconductor region is selected from the group consisting of: Si₁₋ₓGeₓ and Si_{1-x-y}GeₓC_{y}.

11. The vertical transistor of claim 10, wherein x ranges approximately from 0.05 to 0.8 and y is approximately less than 0.02.

12. The vertical transistor of claim 1, wherein said semiconductor region is implanted with a dopant selected from the group consisting of: germanium and carbon.

13. An integrated circuit comprising an array of memory cells each comprising a vertical transistor positioned above a trench capacitor and electrically coupled to said trench capacitor, said vertical transistor comprising:
a substrate having an insulator layer formed thereon and a trench formed in said substrate and said insulator layer, said trench having an upper section with sidewalls extending through said insulator layer to an upper surface of said substrate and having a lower section with sidewalls extending from said upper substrate surface into said substrate;
a semiconductor region formed adjacent to at least one of said upper trench sidewalls;
an upper terminal region and a lower terminal region formed in said semiconductor region, wherein said upper terminal region is separated from said lower terminal region by a channel region;
a gate insulator extending from said source region to said drain region and in contact with said channel region; and
a gate conductor formed on said gate insulator, said gate insulator isolating said gate conductor from said channel region.

14. The integrated circuit of claim 13, further comprising logic circuitry in addition to said memory cells.

15. The integrated circuit of claim 14, wherein said logic circuitry is selected from the group consisting of: CMOS circuitry, bipolar circuitry, BiCMOS circuitry, and system-on-chip circuitry.

16. A method of forming a vertical transistor, comprising:
providing a substrate having an insulator layer formed thereon;
forming an upper trench section in said insulator layer;
forming a sacrificial spacer adjacent to at least one side- wall of said upper trench section;
forming a lower trench section in said substrate, wherein said upper and lower trench sections are aligned and form a trench;
forming a semiconductor region adjacent to at least one sidewall of said upper trench section;
forming a lower terminal region in a lower portion of said semiconductor region;
forming a gate insulator adjacent to a channel region of said semiconductor region;
forming a gate conductor on said gate insulator; and
forming an upper terminal region in an upper portion of said semiconductor region.

17. The method of claim 16, further comprising forming a trench capacitor in said lower trench section, comprising:
forming a first node in said substrate;
forming a node dielectric adjacent to said first node;
forming a second node adjacent to said node dielectric, wherein said node dielectric isolates said second node from said first node; and
forming a buried strap adjacent to said lower terminal region, wherein said buried strap couples said lower terminal region to said second node.

18. The method of claim 16, wherein the step of forming said lower terminal region comprises outdiffusing a dopant from said buried strap into said lower portion of said semiconductor region.

19. The method of claim 16, prior to forming said upper trench section, further comprising:
forming a blocking cap layer on said insulator layer; and
forming a pad layer on said blocking cap layer over a first portion of said substrate, wherein the step of forming said upper trench section comprises forming said upper trench section in said blocking cap layer and said insulator layer.

20. The method of claim 19, further comprising forming logic circuitry in said first substrate portion.
